(19) United States
(12) Patent Application Publication
(10) Pub. No.: US 2026/0169071 A1
(43) Pub. Date: Jun. 18, 2026

(54) MONITORING SOLUTIONS FOR ELECTRICAL SYSTEMS

(71) Applicant: ABB Schweiz AG, Baden (CH)

(72) Inventors: David Salido Monzu, Zürich (CH); Andreas Port, Opfikon (CH); Agostino Butti, Milano (IT); Luca Ghezzi, Gallarate (IT)

(21) Appl. No.: 19/387,815

(22) Filed: Nov. 13, 2025

(30) Foreign Application Priority Data
Dec. 16, 2024 (EP) 24220066.5

(51) Int. Cl. G01R 31/327; G01R 29/06; G01R 31/42

(52) U.S. Cl. CPC G01R 31/3277; G01R 29/06; G01R 31/42

(57) ABSTRACT

A method for probing a circuit breaker electrically connected to an electric line is described. The probing method comprises injecting a first signal at a first point of said electric line. The probing method further comprises detecting a second signal at a second point of said electric line. The probing method further comprises processing a first portion of said second signal, to calculate a first signal value indicative of the signal power of said second signal in the frequency band of said first signal, during the first portion of said detection time interval. The probing method further comprises processing a second portion of said second signal, to calculate a second signal value indicative of the signal power of said second signal in the frequency band of said first signal, during the second portion of said detection time interval.

### CROSS REFERENCE TO RELATED APPLICATIONS

The present application claims priority to European Patent Application No. 24220066.5 filed on Dec. 16, 2024, and titled “IMPROVED MONITORING SOLUTIONS FOR ELECTRICAL SYSTEMS”, which is hereby incorporated by reference in its entirety.

### TECHNICAL FIELD

The present disclosure relates to the field of electrical systems, in some embodiments, operating at low-voltage levels. More particularly, the present disclosure relates to an improved method for probing a circuit breaker in an electrical system. The probing method, according to the present disclosure, can be advantageously adopted in monitoring methods for determining an operating state of a circuit breaker. According to a further aspect, the present disclosure relates to a monitoring device for determining an operating state of a circuit breaker, which is configured to carry out the probing method of the present disclosure.

### BACKGROUND

Generally, low-voltage electrical systems, such as electrical installations at residential, commercial business or industrial sites, include a number of circuit breakers configured to implement protection functionalities of specific electrical lines or grid sections.

Normally, circuit breakers have standardized dimensions and are mounted on installation rails arranged in suitable electrical panels. Typically, these devices can take a closed state, at which an electrical current is allowed to flow along a corresponding electrical line, and a tripped state or open state, at which an electrical current flowing along said electrical line is interrupted.

Nowadays, several applications, for example, most recent smart-home systems or electrical installations including distribution and sub-distribution panels at different physical locations, require that the operating conditions of the installed circuit breakers be monitored in order to ensure a fast intervention in case of a fault.

Most traditional solutions designed for the purpose of monitoring the operating state of a circuit breaker foresee that a side accessory is mechanically coupled to the circuit breaker in order to switch together with this latter and signal the operating state of the circuit breaker through a suitable I/O interface. Unfortunately, these solutions may be difficult to employ (for example, during retrofitting interventions) as an additional space in proximity of the circuit breaker has to be foreseen on the installation rails to allow the above-mentioned accessory device to be mounted.

Patent document EP4119959A1 discloses a device for monitoring the operating state of a circuit breaker in a low-voltage electrical system.

The monitoring device disclosed in the above-mentioned patent document is configured to probe the circuit breaker by injecting and detecting signals through the electric line, on which the circuit breaker is installed, and determine the operating status of the circuit breaker based on the detection signals acquired through the above-mentioned probing activity.

The monitoring device comprises a signal transceiver comprising a transmitter arrangement, which is operatively coupled to an electric line at a first point, and receiver arrangement, which is operatively coupled to said electric line, at a second point.

The transmitter arrangement is configured to generate a first signal and inject this latter into the electric line at the above-mentioned first point. The receiver arrangement is configured to receive a second signal from the electric line at the second point in response to the injection of the above-mentioned first signal by the transmitter arrangement.

The disclosed monitoring device further comprises a signal processor, which is operatively coupled to the signal transceiver and is configured to determine the state of the circuit breaker by suitably processing the second signal received by the receiver arrangement of the signal transceiver.

A remarkable advantage of the monitoring devices of this type consists in that they are characterized by a high flexibility in installation. In fact, they do not need to be mechanically coupled to a circuit breaker and, therefore, they do not have to be mounted on the installation rails in the immediate vicinity of the circuit breaker.

These monitoring devices can thus be installed in operating positions suitably selected depending on the physical configuration of the electrical panel, for example between the installation rails or on the top or bottom of the installed circuit breakers.

Notwithstanding the above, these monitoring devices have still some aspects to improve.

The performances of these monitoring devices are highly influenced by the background noise either injected from the grid (in other words, the main power line typically upstream from the circuit breaker with reference to the main direction of the electric power flow along the electric line) or generated by electric loads electrically connected to the electric line (typically downstream from the circuit breaker with reference to the main direction of the electric power flow along the electric line).

High noise levels having frequencies included in the frequency band of the injected signal can greatly contribute to increase the detected signal level and lead to an overestimation of this latter. The determination process of the operating state of the circuit breaker can thus lead to a wrong evaluation of the operating state of the circuit breaker, typically to a false positive determination of a closed state.

In the market, it is quite felt the need for innovative solutions able to overcome or mitigate the above-mentioned technical issues of these recent solutions of the state of the art.

### BRIEF DESCRIPTION

The present disclosure intends to respond to this need by providing a method for probing a circuit breaker. The objects of the present disclosure are achieved by the subject-matter of the independent claim. Further exemplary embodiments are evident from the dependent claims and the following description. The embodiments and features, if any, described in this specification that do not fall under the scope of the independent claim are to be interpreted as examples useful for understanding various embodiments of the present disclosure.

According to an aspect of the present disclosure, a method for probing a circuit breaker electrically connected to an electric line is provided. The method comprises injecting a first signal at a first point of the electric line, wherein the first signal has a predefined frequency content and a predefined frequency band and is injected during an injection time interval having a predefined time duration; detecting a second signal at a second point of the electric line, wherein the second signal is detected during a detection time interval including at least partially the injection time interval; processing a first portion of the second signal, which refers to a first portion of the detection time interval during which the first signal is injected, to calculate a first signal value indicative of the signal power of the second signal in the frequency band of the first signal, during the first portion of the detection time interval; and processing a second portion of the second signal, which refers to a second portion of the detection time interval during which the first signal is not injected, to calculate a second signal value indicative of the signal power of the second signal in the frequency band of the first signal, during the second portion of the detection time interval.

According to another aspect, the method further comprises cyclically injecting the first signal, detecting the second signal, processing the first portion of the second signal, and processing the second portion of the second signal, to calculate a sequence of first signal values and a sequence of second signal values at subsequent time instants; and processing the calculated sequences of first and second signal values to determine an operating state of the circuit breaker.

According to another aspect, a device for monitoring an operating state of a circuit breaker electrically connected to an electric line is provided. The monitoring device is configured to: inject a first signal at a first point of the electric line, wherein the first signal has a predefined frequency content and a predefined frequency band and is injected during an injection time interval having a predefined time duration; detect a second signal at a second point of the electric line, wherein the second signal is detected during a detection time interval including at least partially the injection time interval; process a first portion of the second signal, which refers to a first portion of the detection time interval during which the first signal is injected, to calculate a first signal value indicative of the signal power of the second signal in the frequency band of the first signal, during the first portion of the detection time interval; and process a second portion of the second signal, which refers to a second portion of the detection time interval during which the first signal is not injected, to calculate a second signal value indicative of the signal power of the second signal in the frequency band of the first signal, during the second portion of the detection time interval.

According to another aspect, a low-voltage electrical system is provided. The low-voltage electrical system comprises: an electric line; a circuit breaker electrically connected between a first line section and a second line section of the electric line; and a monitoring device configured to monitor an operating state of the circuit breaker, wherein the monitoring device is electrically connected to the electric line at a first point of the electric line and at a second point of the electric line. The monitoring device is configured to: inject a first signal at a first point of the electric line, wherein the first signal has a predefined frequency content and a predefined frequency band and is injected during an injection time interval having a predefined time duration; detect a second signal at a second point of the electric line, wherein the second signal is detected during a detection time interval including at least partially the injection time interval; process a first portion of the second signal, which refers to a first portion of the detection time interval during which the first signal is injected, to calculate a first signal value indicative of the signal power of the second signal in the frequency band of the first signal, during the first portion of the detection time interval; and process a second portion of the second signal, which refers to a second portion of the detection time interval during which the first signal is not injected, to calculate a second signal value indicative of the signal power of the second signal in the frequency band of the first signal, during the second portion of the detection time interval.

### BRIEF DESCRIPTION OF DRAWINGS

The subject matter of the present disclosure will be explained in more detail in the following text with reference to exemplary embodiments which are illustrated in the attached drawings.

FIG. 1 is a schematic view showing an electrical system including a circuit breaker and a monitored device operatively associated to said circuit breaker and capable of carrying out the monitoring method according to an embodiment of the present disclosure.

FIGS. 2, 2A, 2B, 2C, and 3 are schematic diagrams showing the operating activities of the probing method according to an embodiment of the present disclosure.

FIGS. 4-5 are schematic diagrams showing the operating activities of a monitoring method of the operating state of a circuit breaker, which includes the probing method according to an embodiment of the present disclosure.

The reference symbols used in the drawings, and their meanings, are listed in summary form in the list of reference symbols. In principle, identical parts are provided with the same reference symbols in the figures.

### DETAILED DESCRIPTION

Reference will now be made in detail to the various embodiments, one or more examples of which are illustrated in each figure. Each example is provided by way of explanation and is not meant as a limitation. For example, features illustrated or described as part of one embodiment can be used on or in conjunction with any other embodiment to yield yet a further embodiment. It is intended that the present disclosure includes such modifications and variations.

Within the following description of the drawings, the same reference numbers refer to the same or to similar components. In some instances, the same or similar components may be assigned a different reference number, for example, due to a different configuration within the electronic circuit. Generally, only the differences with respect to the individual embodiments are described. Unless specified otherwise, the description of a part or aspect in one embodiment applies to a corresponding part or aspect in another embodiment as well.

With reference to the above-mentioned figures, the present disclosure concerns improved monitoring solutions for electrical systems (for example, electric grids, electric switchgear systems, electric switchboards, and the like), which, in some embodiments, operate at low-voltage levels, in other words, at voltage levels lower than 1.5 kV AC and 2.0 kV DC.

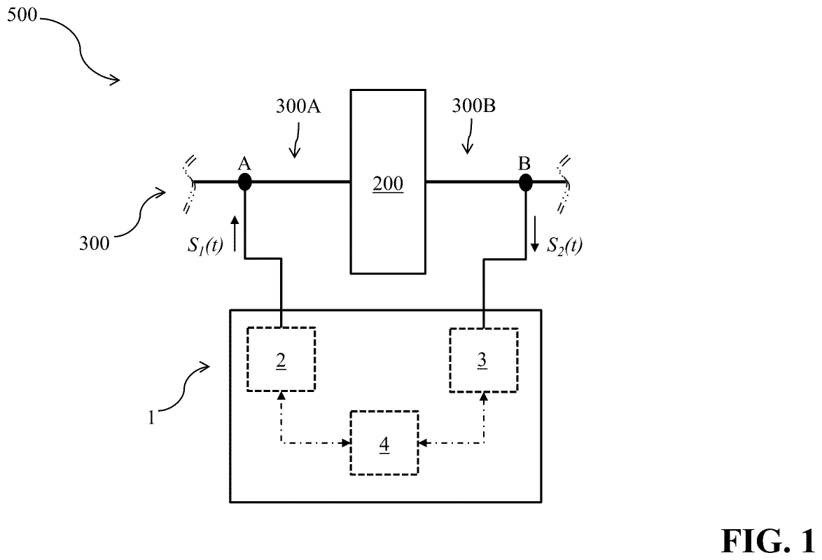

FIG. 1 shows an exemplary electrical system 500 operating at low-voltage levels.

The electrical system 500 comprises a low-voltage electric line 300, which is intended to connect electrically two different grid sections, each of which may include one or more electric power sources and/or one or more electric loads.

The electric line 300 can comprise one or more phase conductors and, possibly, also a neutral conductor. As an example, the electric line 300 may be arranged according to a 1P+N configuration, a 3P configuration, a 3P+N configuration, or a 2P+N configuration.

The electrical system 500 comprises a circuit breaker 200 operatively coupled to the electric line 300. Namely, the circuit breaker 200 is electrically connected between a first line section 300A and a second line section 300B of the electric line 300.

The circuit breaker 200 may be of any type adapted for the employment in an electrical system operating at AC or DC low-voltage levels. For example, it may be a MCB (Miniature Circuit Breaker), a RCCB (Residual Current Circuit Breaker) device, or a RCBO (Residual Current circuit Breaker with Overcurrent protection) device, or a RCM (Residual Current Monitor) device, or the like.

In operation, the circuit breaker 200 can take a closed state, at which it allows the flow of a current along the electric line 300, or can take an open or tripped state, at which it prevents a current to flow along the electric line 300.

A transition from a closed state to an open or tripped state forms an opening maneuver or a tripping maneuver of the circuit breaker 200 while a transition from an open or tripped state to a closed state forms a closing maneuver of the circuit breaker.

Depending on how the electrical system 500 is configured, the energy flow along the electric line 300 can be directed from the first line section 300A to the second line section 300B, or vice-versa. For the circuit breaker 200, each of the line sections 300A, 300B may thus be considered as an input power supply line or an output power supply line depending on the main direction of the electric power flow.

In general, the electric line 300 and the circuit breaker 200 of the electrical system 500 may be realized according to solutions of known type. In the following, these elements will thus not be described in more details for the sake of brevity.

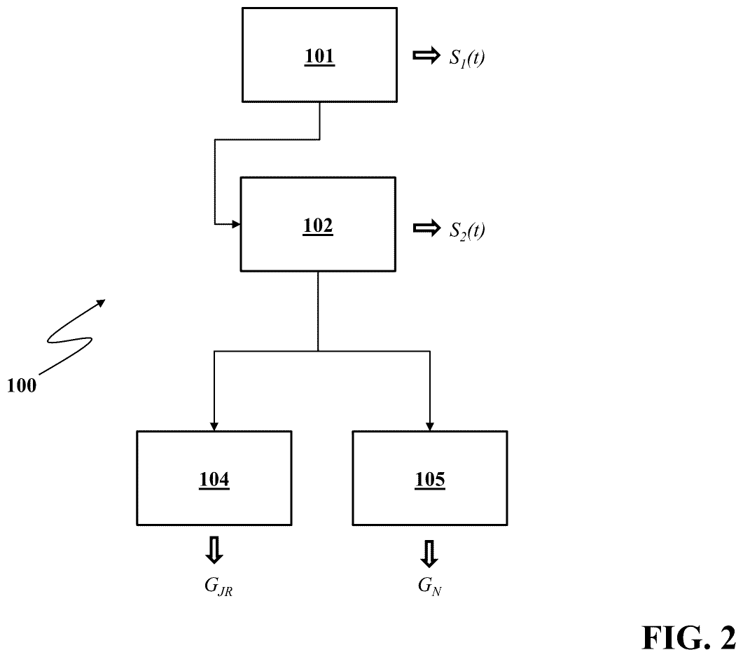

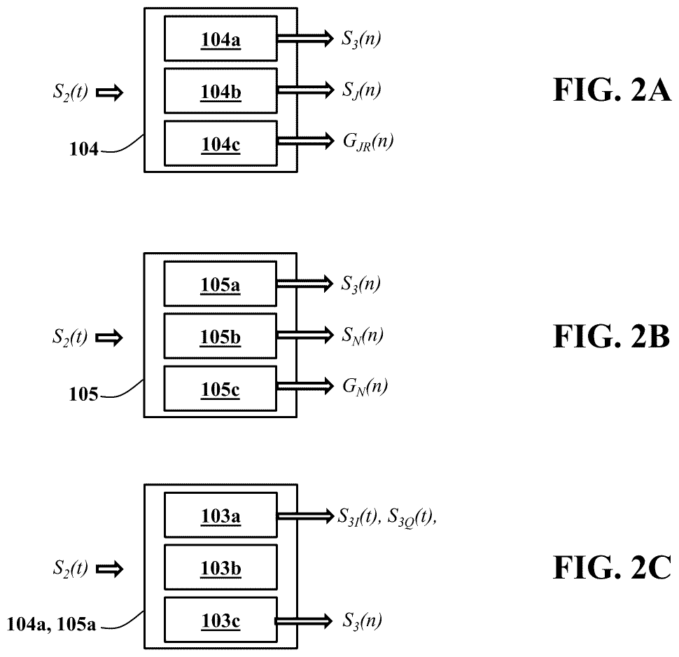

Referring now to FIG. 2, the present disclosure relates to an improved probing method 100 of a circuit breaker in an electrical system.

According to the present disclosure, the probing method 100 comprises an activity 101, in which a first signal S₁(t) is generated and injected at a first point A (injection point) of the electric line 300.

In the embodiment shown in FIG. 1, the first point A, at which the first signal S₁(t) is injected, is located at the first line section 300A of the electric line. In principle, however, it can be positioned also at the second line section 300B of the electric line.

In some embodiments, the first signal S₁(t) is an AC signal.

In some embodiments, the first signal S₁(t) is a current or voltage signal having a high frequency content (compared to the mains frequency), for example in the order of MHz.

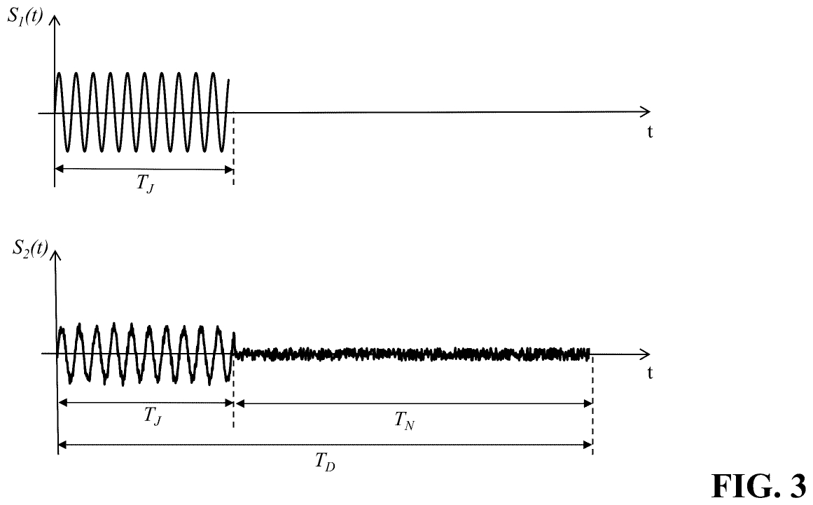

The first signal S₁(t) has predefined center frequency value and frequency band, and it is injected during an injection time interval T_{J} having a predefined time duration (FIG. 3).

As an example, the first signal S₁(t) may be a windowed sinusoidal signal having a frequency value of 1 MHz and injected for an injection time interval T_{J}=10 ms.

According to the present disclosure, the probing method 100 comprises an activity 102, in which a second signal S₂(t) is detected at a second point B (detection point) of the electric line 300.

In the embodiment shown in FIG. 1, the second point B, at which the second signal S₂(t) is detected, is located at the second line section 300B of the electric line. In principle, however, it can be positioned also at the first line section 300A of the electric line.

In some embodiments, the second signal S₂(t) is an AC signal.

In some embodiments, the second signal S₂(t) is a current or voltage signal having a high frequency content (compared to the mains frequency), for example in the order of MHz.

The second signal S₂(t) is detected for a detection time interval T_{D}, which at least partially includes the injection time interval T_{J} (FIG. 3).

In some embodiments, the injection of the first signal S₁(t) and the detection of the second signal S₂(t) are synchronized, for example through a suitable synchronization or event detection method (which may be of known type), so that the injection time interval Tris included in the detection time interval T_{D}.

In some embodiments, the detection time interval T_{D} can be expressed as:

$${T}_{D} = {T}_{J} + {T}_{N}$$

where T_{J} is a first portion of the detection time interval T_{D}, during which the first signal S₁(t) is injected, and IN is a second portion of the detection time interval T_{D}, during which the first signal S₁(t) is not injected.

In principle, however, the injection time interval T_{J} may start at any time during the detection time interval T_{D}. Consequently, the above-mentioned time portions T_{J}, T_{N} of the detection time interval T_{D} can be arbitrarily foreseen during the detection time interval T_{D} provided that they do not overlap each other and are covered by the detection time interval T_{D}.

According to the present disclosure, the probing method 100 comprises an activity 104 of processing a first portion of the second signal S₂(t), which refers to the first portion T_{J} of the detection time interval T_{D}, during which the first signal S₁(t) is injected, to calculate a first signal value G_{JR} indicative of the signal power of the second signal S₂(t) in the frequency band of the first signal S₁(t), during the first portion T_{J} of the detection time interval T_{D}.

The first signal value G_{JR} is indicative of the magnitude of the signal components provided by the electric line in response to the injection of the first signal S₁(t). In accordance with the above, the calculated first signal value G_{JR} depends on both the operating state of the circuit breaker 200 and the background noise of the electric line 300.

According to the present disclosure, the probing method 100 comprises an activity 105 of processing a second portion of the second signal S₂(t), which refers to the second portion T_{J} of the detection time interval T_{D}, during which the first signal S₁(t) is not injected, to calculate a second signal value G_{N} indicative of the signal power of the second signal S₂(t) in the frequency band of the first signal S₁(t), during the second portion T_{J} of the detection time interval T_{D}.

The second signal value G_{N} is indicative of the magnitude of the background noise of the electric line, which depends on a number of factors such as the layout and type of the electric loads electrically connected to the electric line.

The calculation of the above-mentioned quantities G_{JR}, G_{N} allows decorrelating signal components, which are useful to determine the operating state of the monitored circuit breaker from the undesired background noise of the electric line 300. The operating state of the circuit breaker 200 can thus be estimated based on the calculation of these quantities.

In principle, the above-mentioned activities 104, 105 of the method of the present disclosure can be carried out through analog or digital signal processing means, according to the needs.

In some embodiments, they are carried out exploiting digital signal processing resources. In this case, the above-mentioned activities 104, 105 of the method of the present disclosure advantageously includes the sub-activities described in FIGS. 2A, 2B, and 2C.

In some embodiments, the activity 104 of the method 100 comprises a sub-activity 104a of processing the detected second signal S₂(t) to obtain a digital signal S₃(n) indicative of the magnitude of the second signal S₂(t) in the frequency band of the injected first signal S₁(t).

In some embodiments, the activity 104 of the method 100 comprises a sub-activity 104b of selecting a first time-series S_{J}(n) of signal samples from the calculated digital signal S₃(n). The first time-series S_{J}(n) of signal samples refers to time instants included in the first portion T_{J} of the detection time interval T_{D}, during which the first signal S₁(t) is injected.

The first time series S_{J}(n) of signal samples allows observing the signal level provided by the electric line 300 in response to the injection of the first signal S₁(t). During this portion of the detection time interval T_{D}, however, both signal components useful to determine the operating state of the circuit breaker and the background noise of the electric line are overlapped, and the background noise can greatly contribute to the detected signal level.

In some embodiments, the activity 104 of the method 100 comprises a sub-activity 104c of processing the first time-series S_{J}(n) of signal samples to calculate a first signal value G_{JR} indicative of the signal power of the second signal S₂(t) in the frequency band of the first signal S₁(t), during the first portion T_{J} of the detection time interval T_{D}.

As mentioned above, the first signal value G_{JR} is indicative of the signal power of the signal components provided by the electric line in response to the injection of the first signal S₁(t). In accordance with the above, the calculated first signal value G_{JR} depends on both the operating state of the circuit breaker 200 and the background noise of the electric line 300.

In some embodiments, the first signal value G_{JR} is calculated as a statistical quantity (for example, average power) indicative of the signal power of the first time-series S_{J}(n) of signal samples. To this aim, well known signal processing techniques can be adopted.

For example, when the second signal S₂(t) is demodulated through an I/Q demodulation process, the signal value G_{JR} of the electric line may be calculated based on the following relationship:

$${G}_{JR} = \frac{1}{P} {\sum }_{i = 1}^{P} \sqrt{{{x}_{3 I} ( i )}^{2} + {{x}_{3 Q} ( i )}^{2}}$$

where x_{3I}(i), x_{3Q}(i) are a generic pair of signal samples of the digital signal S_{J}(n) and P is the number of pairs of signal samples included in the first time-series S_{J}(n).

In some embodiments, the activity 105 of the method 100 comprises a sub-activity 105a of processing the detected second signal S₂(t) to obtain a digital signal S₃(n) indicative of the magnitude of the second signal S₂(t) in the frequency band of the injected first signal S₁(t).

In some embodiments, the activity 105 of the method 100 comprises a sub-activity 105b of selecting a second time-series S_{N}(n) of signal samples from the calculated digital signal S₃(n).

The second time-series S_{N}(n) of signal samples refers to time instants included in the portion T_{N} of the detection time interval T_{D}, during which the first signal S₁(t) is not injected.

During the portion T_{N} of the detection time interval T_{D}, the injection of the first signal S₁(t) is terminated and the detected second signal S₂(t) is formed by the sole background noise of the electric line. The second time series S_{N}(n) of signal samples thus allows observing the background noise level of the electric line 300 in a frequency band corresponding to the frequency band of the first signal S₁(t).

In some embodiments, the activity 105 of the method 100 comprises a sub-activity 105c of processing the second time-series S_{N} of signal samples to calculate a second signal value G_{N} indicative of the signal power of the second signal S₂(t) in the frequency band of the first signal S₁(t), during the second portion T_{N} of the detection time interval T_{D}.

As mentioned above, the second signal value G_{N} is indicative of the magnitude of the background noise of the electric line, which depends on a number of factors such as the layout and type of the electric loads electrically connected to the electric line.

In some embodiments, the background noise level G_{N} is calculated as a statistical quantity (for example, standard deviation) indicative of the variability of the second time-series S_{N}(n) of signal samples, which is indicative of the background noise average power.

In order to calculate this quantity, well known signal processing techniques can also be adopted. For example, when the second signal S₂(t) is demodulated through an I/Q demodulation process, a second signal value G_{N} related to the electric line may be calculated based on one of the following relationships:

$${G}_{N} = \sqrt{{\sum }_{i = 1}^{M} \frac{1}{M} {( {x}_{3 I} ( i ) - {x}_{0} )}^{2}} or {G}_{N} = \sqrt{{\sum }_{i = 1}^{M} \frac{1}{M} {( {x}_{3 Q} ( i ) - {x}_{0} )}^{2}}$$

where x_{3I}(i), x_{3Q}(i) are a generic pair of signal samples of the digital signal S_{N}(n), x₀ is the average value of S_{N}(n) and M is the number of pairs of signal samples included in the second time-series S_{N}.

As mentioned above, being carried out through digital signal processing resources, the activities 104, 105 of the method 100 comprise respectively the sub-activities 104a, 105a of processing the detected second signal S₂(t) to obtain a digital signal S₃(n) indicative of the magnitude of the second signal S₂(t) in the frequency band of the injected first signal S₁(t).

In some embodiments, the above-mentioned sub-activities 104a, 105a comprise the sub-activity 103a of calculating a pair of signals S_{3I}(t), S_{3Q}(t) by demodulating the detected second signal S₂(t).

The demodulation of the second signal S₂(t) can be carried out according to well-known signal processing techniques, for example according to an I/Q demodulation process.

In this case, the pair of signals S_{3I}(t), S_{3Q}(t) are sinusoidal signals in quadrature representing down converted versions of the second signal S₂(t), which are calculated by multiplying this last signal by suitable reference sinusoidal signals mutually in quadrature and having a predefined frequency.

In some embodiments, the above-mentioned sub-activities 104a, 105a comprise the sub-activity 103b of filtering the calculated pair of signals S_{3I}(t), S_{3Q}(t) with a filter having a bandwidth narrow with respect to the center frequency of the first signal S₁(t).

In some embodiments, the above-mentioned filter had a bandwidth

$${B}_{w} < \frac{1}{10} {f}_{c} ,$$

where fc is the center frequency of the first signal S₁(t).

As the pair of signals S_{3I}(t), S_{3Q}(t) are obtained by multiplying the detected second signal S₂(t) with suitable frequency reference signals (demodulation), filtering is needed to discard spurious frequency components resulting from this mixing.

The filtering process of the signals S_{3I}(t), S_{3Q}(t) can be also carried out according to well-known signal processing techniques, for example according to band-pass or low-pass filtering process.

In some embodiments, the above-mentioned sub-activities 104a, 105a comprise the sub-activity 103c of sampling the filtered signals S_{3I}(t), S_{3Q}(t) so obtained with a sampling rate that basically depends on the center frequency of the first signal S₁(t).

More precisely, the sampling rate is calculated based on a down converted frequency, which is defined by the relationship between the center frequency of the first signal S₁(t) and the frequency of the reference signals used to demodulate the second signal S₂(t). The sampling process of the filtered signals S_{3I}(t), S_{3Q}(t) can be also carried out according to well-known signal processing techniques.

It is apparent from the above how the digital signal S₃(n) includes a pair of samples x_{3I}(i), x_{3Q}(i) at each generic iₜₕ-instant (sampling instant). Each pair of samples x_{3I}(i), x_{3Q}(i) is obtained by sampling the filtered signals S_{3I}(t), S_{3Q}(t), which are in turn obtained by demodulating the detected second signal S₂(t).

The digital signal S₃(n) so obtained is thus indicative of the magnitude of the second signal S₂(t) in the frequency band of the first signal S₁(t).

As mentioned above, the calculation of the above-mentioned quantities G_{JR}, G_{N} allows estimating the operating state of the circuit breaker 200.

The probing method 100 of the present disclosure can be advantageously employed in methods for monitoring the state of a circuit breaker to collect information indicative of the operating state of this latter.

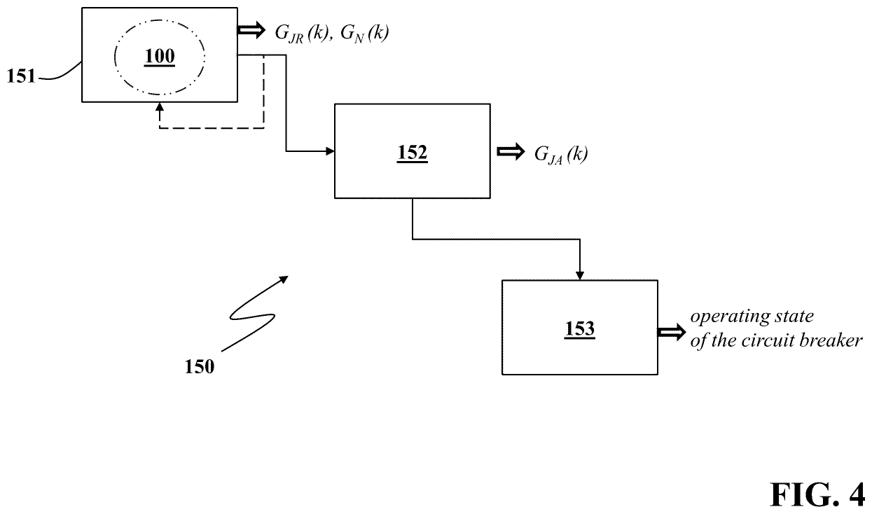

FIG. 4 shows an exemplary embodiment of a method 150 for monitoring the operating state of a circuit breaker.

The monitoring method 150 comprises a activity 151 of repeating cyclically the probing method 100 of the present disclosure to calculate a sequence of first signal values G_{JR}(k) and a sequence of second signal values G_{N}(k) related to the electric line 300 at subsequent instants in time.

The monitoring method 150 then comprises processing the calculated sequences of first signal values G_{JR}(k) and second signal values G_{N}(k) to determine an operating state of the circuit breaker.

In some embodiments, the monitoring method 150 comprises the processing activity 152 of calculating a sequence of adjusted signal values G_{JA}(k) related to the electric line based on the above-mentioned sequences of first signal values G_{JR}(k) and second signal values G_{N}(k), which are calculated by cyclically carrying out the probing method 100 of the present disclosure.

An adjusted signal value G_{JA}(k) of the electric line at a generic kₜₕ-cycle may be simply calculated based on the following relationship:

$${G}_{JA} ( k ) = {G}_{JR} ( k ) - {G}_{N} ( k )$$

where G_{JR}(k), G_{N}(k) are the above-mentioned first signal value and second signal value at the same generic kₜₕ-cycle, which may be calculated as illustrated above.

The sequence of adjusted signal values G_{JA}(k) is indicative of the magnitude of the sole signal components provided by the electric line in response to the injection of the first signal S₁(t), which are useful to determine the operating state of the circuit breaker.

Each adjusted signal value G_{JA}(k) of the electric line is a quantity that basically depends on the operating state of the circuit breaker during the time when the measurement cycle k was carried out. Such a quantity is substantially immune from the background noise of the electric line. Therefore, the calculated sequence of adjusted signal values G_{JA}(k) can be used for monitoring the behavior of the circuit breaker in a robust and reliable manner.

In some embodiments, the monitoring method 150 comprises the processing activity 153 of comparing the calculated sequence of adjusted signal values G_{JA}(k) with one or more threshold values V_{TH1}, V_{TH2} to determine the operating state of the circuit breaker. Based on the result of this comparison, the operating state of the circuit breaker can be determined.

In some embodiments, said threshold values are predefined. As an example, they can be derived from reference data acquired in controlled conditions with known breaker statuses.

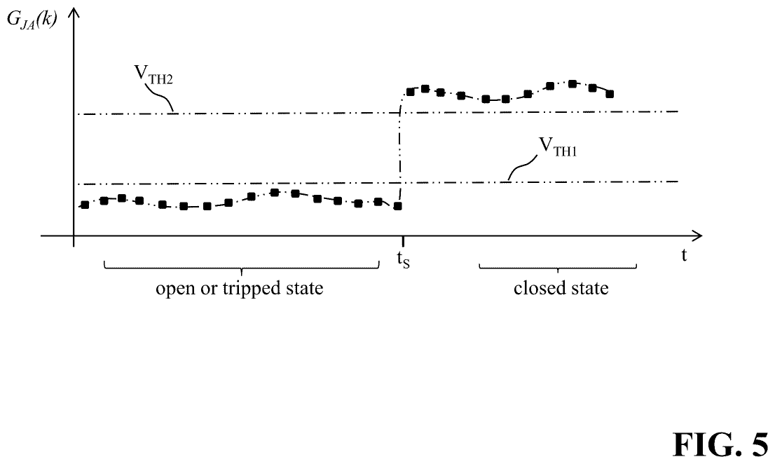

FIG. 5 shows an exemplary representation of a sequence of adjusted signal values G_{JA}(k) obtained during the execution of a closing maneuver by the circuit breaker 200 shown in the above-mentioned FIG. 1.

As it is possible to notice, the calculated adjusted signal values G_{JA}(k) are relatively low before the switching instant t_{S} (circuit breaker in an open or tripped state) and are relatively high after the switching instant t_{S} (circuit breaker in a closed state).

By comparing the calculated adjusted signal values G_{JA}(k) with a lower threshold value V_{TH1} and with a higher threshold value V_{TH2}, it is possible to determine the operating state of the circuit breaker.

According to other embodiments of the present disclosure, the above-mentioned sequences of first signal values G_{JR}(k) and second signal values G_{N}(k), which are calculated by cyclically carrying out the probing method 100 of the present disclosure, are processed through suitable two-dimensional classification methods.

For example, each pair of first signal values G_{JR}(k) and second signal values G_{N}(k) can be interpreted as coordinates in a two-dimensional plane. A threshold value can be defined in this plane based on reference data acquired in controlled conditions with known breaker statuses, thus dividing the two-dimensional space into two sub-planes. By evaluating in which of these sub-planes the coordinates defined by G_{JR}(k) and G_{N}(k) reside, the operating state of the circuit breaker can be determined.

In a further aspect, the present disclosure relates to a monitoring device 1 for monitoring an operating state of the circuit breaker 200.

Referring back to FIG. 1, the monitoring device 1, in some embodiments, comprises a signal transceiver module 2, 3 and a signal processor module 4.

The signal transceiver module comprises a transmitter arrangement 2, which is operatively coupled (for example, in a capacitive or inductive manner) to the electric line 300 at the first point A of this latter, and a receiver arrangement 3, which is operatively coupled (for example, in a capacitive or inductive manner) to the electric line 300, at the second point B of this latter.

The signal processor module 4 is operatively coupled with the signal transmitter arrangement 2 and the receiver arrangement 3 in such a way to exchange data signals and command signals with both.

In many aspects, the monitoring device 1 can be realized industrially according to solutions of known type, for example according to the solutions described in the above-mentioned patent document EP4119959A1.

However, the monitoring device 1 is equipped with signal processing means (which may be of digital and/or analog type) configured to carry out the probing method 100 of the present disclosure described above.

In some embodiments, the monitoring device 1 is equipped also with signal processing means (which may be of digital and/or analog type) configured to carry out the monitoring method 150 described above.

In an electrical system 500 (AC or DC), the monitoring device 1 can be mounted onboard or integrated in the circuit breaker 200 or constitute a separate unit from this latter. In this case, the monitoring device 1 does not need to be mounted in the immediate vicinity of the circuit breaker but it can be advantageously mounted in a suitable position within an electrical switchboard or panel.

It has been seen in practice how the monitoring solutions provided by the present disclosure provide relevant technical advantages over the state of the art.

The probing method, according to the present disclosure, allows collecting information indicative of the operating state of the circuit breaker, which is substantially decorrelated from the background noise of the electric line on which the circuit breaker is mounted.

This allows monitoring the operating state of a circuit breaker in a robust and reliable manner, substantially independent from the background noise injected from the grid or generated by the electric loads electrically connected to the electric line.

The solution proposed by the present disclosure can therefore be employed in a monitoring method or monitoring device to allow a more efficient and safer determination process of the operating state of a circuit breaker, which reduces the risk that faults or malfunctions of the electrical system remain unattended and favors the execution of urgent interventions in case of faults.

The probing method, according to the present disclosure, requires relatively small computational resources to be carried out and is relatively easy and cheap to implement at industrial level.

The monitoring method and the monitoring device, according to the present disclosure, are also relatively easy to implement at industrial level at competitive costs with currently available solutions of the state of the art.

While the present disclosure has been illustrated and described in detail in the drawings and foregoing description, such illustration and description are to be considered illustrative or exemplary and not restrictive; the present disclosure is not limited to the disclosed embodiments. Other variations to the disclosed embodiments can be understood and effected by those skilled in the art and practicing the present disclosure, from a study of the drawings, the disclosure, and the appended claims. In the claims, the word “comprising” does not exclude other elements or activities, and the indefinite article “a” or “an” does not exclude a plurality. A single processor or controller or other unit may fulfil the functions of several items recited in the claims. The mere fact that certain measures are recited in mutually different dependent claims does not indicate that a combination of these measures cannot be used to advantage. Any reference signs in the claims should not be construed as limiting the scope.

The disclosed systems and methods are not limited to the specific embodiments described herein. Rather, components of the systems or activities of the methods may be utilized independently and separately from other described components or activities.

This written description uses examples to disclose various embodiments, which include the best mode, to enable any person skilled in the art to practice those embodiments, including making and using any devices or systems and performing any incorporated methods. The patentable scope is defined by the claims and may include other examples that occur to those skilled in the art. Such other examples are intended to be within the scope of the claims if they have structural elements that do not differ from the literal language of the claims, or if they include equivalent structural elements with insubstantial differences form the literal language of the claims.

1. A method for probing a circuit breaker electrically connected to an electric line, characterised in the method comprising:
injecting a first signal at a first point of the electric line, wherein the first signal has a predefined frequency content and a predefined frequency band and is injected during an injection time interval having a predefined time duration;
detecting a second signal at a second point of the electric line, wherein the second signal is detected during a detection time interval including at least partially the injection time interval;
processing a first portion of the second signal, which refers to a first portion of the detection time interval during which the first signal is injected, to calculate a first signal value indicative of the signal power of the second signal in the frequency band of the first signal, during the first portion of the detection time interval; and
processing a second portion of the second signal, which refers to a second portion of the detection time interval during which the first signal is not injected, to calculate a second signal value indicative of the signal power of the second signal in the frequency band of the first signal, during the second portion of the detection time interval.

2. The method according to claim 1, wherein processing the first portion of the second signal:
processing the second signal to obtain a digital signal indicative of the magnitude of the second signal in the frequency band of the first signal;
selecting a first time-series of signal samples from the digital signal, wherein the first time-series of signal samples refers to the first portion of the detection time interval, during which the first signal is injected; and
processing the first time-series of signal samples to calculate the first signal value.

3. The method according claim 1, wherein processing the second portion of the second signal comprises:
processing the second signal to obtain a digital signal indicative of the magnitude of the second signal in the frequency band of the first signal;
selecting a second time-series of signal samples from the digital signal, wherein the second time-series of signal samples refers to the second portion of the detection time interval, during which the first signal is not injected; and
processing the second time-series of signal samples to calculate the second signal value.

4. The method according to claim 2, wherein processing the second signal to obtain the digital signal comprises:
calculating a pair of signals by demodulating the second signal;
filtering the pair of signals with a filter having a bandwidth that is narrow in comparison to the predefined center frequency of the first signal; and
sampling the filtered pair of signals with a sampling rate that is based on the center frequency of the first signal.

5. The method according to claim 4, wherein the second signal is demodulated through an I/Q demodulation process.

6. The method according to claim 1, wherein the first signal value is calculated as a statistical quantity indicative of the signal power of the first time-series of signal samples.

7. The method according to claim 1, wherein the second signal value is calculated as a statistical quantity indicative of the signal power of the second time-series of signal samples.

8. The method according to claim 1, wherein the method further comprises:
cyclically injecting the first signal, detecting the second signal, processing the first portion of the second signal, and processing the second portion of the second signal, to calculate a sequence of first signal values and a sequence of second signal values at subsequent time instants; and
processing the calculated sequences of first and second signal values to determine an operating state of the circuit breaker.

9. A monitoring device for monitoring an operating state of a circuit breaker electrically connected to an electric line, wherein the monitoring device is configured to:
inject a first signal at a first point of the electric line, wherein the first signal has a predefined frequency content and a predefined frequency band and is injected during an injection time interval having a predefined time duration;
detect a second signal at a second point of the electric line, wherein the second signal is detected during a detection time interval including at least partially the injection time interval;
process a first portion of the second signal, which refers to a first portion of the detection time interval during which the first signal is injected, to calculate a first signal value indicative of the signal power of the second signal in the frequency band of the first signal, during the first portion of the detection time interval; and
process a second portion of the second signal, which refers to a second portion of the detection time interval during which the first signal is not injected, to calculate a second signal value indicative of the signal power of the second signal in the frequency band of the first signal, during the second portion of the detection time interval.

10. The monitoring device according to claim 9, wherein the monitoring device is further configured to:
cyclically repeat: injecting the first signal, detecting the second signal, processing the first portion of the second signal, and processing the second portion of the second signal, to calculate a sequence of first signal values and a sequence of second signal values at subsequent time instants; and
process the calculated sequences of first and second signal values to determine an operating state of the circuit breaker.

11. A low-voltage electrical system comprising:
an electric line;
a circuit breaker electrically connected between a first line section and a second line section of the electric line; and
a monitoring device configured to monitor an operating state of the circuit breaker, wherein the monitoring device is electrically connected to the electric line at a first point of the electric line and at a second point of the electric line, and the monitoring device is configured to:
inject a first signal at a first point of the electric line, wherein the first signal has a predefined frequency content and a predefined frequency band and is injected during an injection time interval having a predefined time duration;
detect a second signal at a second point of the electric line, wherein the second signal is detected during a detection time interval including at least partially the injection time interval;
process a first portion of the second signal, which refers to a first portion of the detection time interval during which the first signal is injected, to calculate a first signal value indicative of the signal power of the second signal in the frequency band of the first signal, during the first portion of the detection time interval; and
process a second portion of the second signal, which refers to a second portion of the detection time interval during which the first signal is not injected, to calculate a second signal value indicative of the signal power of the second signal in the frequency band of the first signal, during the second portion of the detection time interval.

12. The monitoring device according to claim 9, wherein in the process the first portion of the second signal, the monitoring device is further configured to:
process the second signal to obtain a digital signal indicative of the magnitude of the second signal in the frequency band of the first signal;
select a first time-series of signal samples from the digital signal, wherein the first time-series of signal samples refers to the first portion of the detection time interval, during which the first signal is injected; and
process the first time-series of signal samples to calculate the first signal value.

13. The monitoring device according to claim 9, wherein in the process the second portion of the second signal, the monitoring device is further configured to:
process the second signal to obtain a digital signal indicative of the magnitude of the second signal in the frequency band of the first signal;
select a second time-series of signal samples from the digital signal, wherein the second time-series of signal samples refers to the second portion of the detection time interval, during which the first signal is not injected; and
process the second time-series of signal samples to calculate the second signal value.

14. The monitoring device according to claim 9, wherein the first signal value is calculated as a statistical quantity indicative of the signal power of the first time-series of signal samples.

15. The monitoring device according to claim 9, wherein the second signal value is calculated as a statistical quantity indicative of the signal power of the second time-series of signal samples.

16. The low-voltage electrical system according to claim 11, wherein in the process the first portion of the second signal, the monitoring device is further configured to:
process the second signal to obtain a digital signal indicative of the magnitude of the second signal in the frequency band of the first signal;
select a first time-series of signal samples from the digital signal, wherein the first time-series of signal samples refers to the first portion of the detection time interval, during which the first signal is injected; and
process the first time-series of signal samples to calculate the first signal value.

17. The low-voltage electrical system according to claim 11, wherein in the process the second portion of the second signal, the monitoring device is further configured to:
process the second signal to obtain a digital signal indicative of the magnitude of the second signal in the frequency band of the first signal;
select a second time-series of signal samples from the digital signal, wherein the second time-series of signal samples refers to the second portion of the detection time interval, during which the first signal is not injected; and
process the second time-series of signal samples to calculate the second signal value.

18. The low-voltage electrical system according to claim 11, wherein the first signal value is calculated as a statistical quantity indicative of the signal power of the first time-series of signal samples.

19. The low-voltage electrical system according to claim 11, wherein the second signal value is calculated as a statistical quantity indicative of the signal power of the second time-series of signal samples.

20. The low-voltage electrical system according to claim 11, wherein the monitoring device is further configured to:
cyclically repeat: injecting the first signal, detecting the second signal, processing the first portion of the second signal, and processing the second portion of the second signal, to calculate a sequence of first signal values and a sequence of second signal values at subsequent time instants; and
process the calculated sequences of first and second signal values to determine an operating state of the circuit breaker.
